(19) United States
(12) Patent Application Publication
(10) Pub. No.: US 2007/0064390 A1
(43) Pub. Date: Mar. 22, 2007

(54) Heat dissipating system and method

(75) Inventors: Dungchang Yeh, Dongguan City (CN); Yungping Lin, Dongguan City (CN)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/365,866

(22) Filed: Mar. 2, 2006

(30) Foreign Application Priority Data
Sep. 22, 2005 (TW) 094132772

(51) Int. Cl. H05K 7/20

(52) U.S. Cl. 361/695

(57) ABSTRACT

A heat dissipating system, which is applied to a heat source, includes a fan and a dust-separating apparatus. The fan rotates and generates an airflow by collecting air from an exterior of the heat dissipating system. The airflow flows into the dust-separating apparatus, and then the dust-separating device separates a dust from the airflow. The separated airflow dissipates the heat from the heat source.

This Non-provisional application claims priority under U.S.C. § 119(a) on Patent Application No(s). 094132772, filed in Taiwan, Republic of China on Sep. 22, 2005, the entire contents of which are hereby incorporated by reference.

### BACKGROUND OF THE INVENTION

1. Field of Invention

The invention relates to a heat dissipating system and, in particular to a heat dissipating system of an electronic apparatus.

2. Related Art

Recently, since the processing speed of electronic apparatuses has become faster and faster, heat generated accompanying with the operation of the electronic apparatuses also increases. If the heat is not dissipated appropriately, the processing speed of the electronic apparatuses may decrease. Even worse, the lifetime of the electronic apparatuses would be affected. Accordingly, a heat sink or a fan is usually applied to an electronic apparatus for dissipating heat.

In the related art, the dust seems an inevitable problem for the heat sink and heat source, so that designers usually take the dust as an unforeseeable item and only consider to reduce thermal resistant of the heat sink for guaranteeing the safety coefficient. In fact, when the dusts are accumulated on the heat sink or heat source, the thermal convection coefficient thereof is affected and thus the heat exchanging effect of the airflow field is reduced. FIG. 1 is a schematic view showing a conventional heat dissipating system of an electronic apparatus. In the electronic apparatus, as shown in FIG. 1, a heat sink 12 is installed on a heat source 11, and the heat sink 12 cooperates with a fan 13 and a filter 14. The fan 13 and the filter 14 are located at one side of the heat sink 12.

The heat of the heat source 11 is conducted to the heat sink 12. When the fan 13 rotates, an airflow is generated to dissipate the heat from the heat sink 12. Also, the filter 14 can be a physical or chemical filter for separating dusts or pollutants from the airflow so as to keep the surfaces of the heat sink 12 and fan 13 clean and prevent from poor heat dissipation due to exceedingly-accumulated dusts. However, the airflow may have a pressure drop after passing through the filter 14. In particular, if the filtering effect is better, the pressure drop caused by the filter 14 becomes larger and the airflow flux is smaller, which results in poor heat dissipating effect. In addition, the filter 14 must be cleaned periodically. If the filter 14 is not cleaned on time, it may lose the filtering function due to the accumulated dusts and, even worse, make the airflow passing through the filter 14 become dirtier. This makes the filter 14 fail to filtering the airflow. Moreover, since the filter 14 is commonly installed within the heat dissipating system, the process for replacing is uneasy when the filter 14 became dirty. Besides, it is difficult to clean the filter directly.

To keep the surfaces of the heat sink 12 and fan 13 clean, another known method is that coating a nano dust-proof material on the surface of the fan 13, or to install a dust-proof device on the impeller of the fan 13 so as to prevent the accumulation of dusts. However, this method can only protect the source of the airflow (the fan 13), and cannot protect the heat sink 14 or the heat source 11. In other words, the dusts may be still accumulated on the heat sink 12 or the heat source 11. As a result, the reliability of the heat dissipation and clean maintenance of the heat sink 12 are actually not improved.

It is therefore an important subject of the invention to provide a heat dissipating system and a heat dissipating method that can reduce the dusts in the heat dissipating system so as to prevent the dusts from being accumulated on the heat source or heat sink. Thus, the heat dissipating system can keep clean and is free from being affected by the accumulated dusts, so that the heat dissipation efficiency can be enhanced.

### SUMMARY OF THE INVENTION

In view of the foregoing, the invention is to provide a heat dissipating system and a heat dissipating method that can reduce the dusts in the heat dissipating system so as to prevent the dusts from being accumulated on the heat source or heat sink. Thus, the heat dissipating system of the invention can keep clean and is free from being affected by the accumulated dusts, so that the heat dissipation efficiency thereof can be enhanced.

To achieve the above, a heat dissipating system of the invention, which is applied to a heat source generating heat, includes a fan and a dust-separating apparatus. The fan rotates and generates an airflow by collecting air from an exterior of the heat dissipating system. After the airflow flows into the dust-separating apparatus, the dust-separating apparatus separates a dust from the airflow, and then the separated airflow dissipates the heat away from the heat source.

The above-mentioned heat dissipating system further includes a heat sink contacting with the heat source. In this case, the heat generated by the heat source is directly conducted to the heat sink, and the separated airflow blows over the heat sink to dissipate the heat away from the heat source. In one aspect, the fan is located adjacent to the heat sink, and the dust-separating apparatus is coupled to the fan, so that the separated airflow directly enters the fan from the dust-separating apparatus and is then blown out from the fan. In another aspect, the dust-separating apparatus is located far from the fan, and the fan is disposed adjacent to the heat source.

In the heat dissipating system of the invention, the fan can be an axial-flow fan or a centrifugal fan, and it is located at an entrance or an exit of the heat dissipating system. The dust-separating apparatus is a cyclonic separator, and the heat source is a electronic device, such as a CPU, memory, chipset, transistor, server, high-level graphic card, hard drive, power supply, vehicle control system, multimedia electronic apparatus, wireless access point, or a high-level game machine (PS3, XBOX, or Nintendo).

In addition, the invention also discloses a heat dissipating method applied to a heat source generating heat. The method includes the following steps of: providing a fan for generating an airflow, separating a dust from the airflow by a dust-separating apparatus, and blowing the airflow over the heat source. In addition, the method may further include the steps of: directly conducting the heat generated by the heat source to a heat sink, and blowing the separated airflow over the heat sink to dissipate the heat away from the heat source.

As mentioned above, the heat dissipating system and method of the invention is to separate the dust carried by the airflow in advance, and then to blow the separated airflow over the heat source. Thus, the dusts in the heat dissipating system can be reduced so as to prevent the dusts from being accumulated on the heat source or heat sink. Accordingly, the heat dissipating system of the invention can keep clean and is free from being affected by the accumulated dusts, so that the heat dissipation efficiency thereof can be enhanced.

To make the above or other objects, features and advantages more comprehensive, a preferred embodiment will be described hereinafter with reference to the accompanying drawings.

### BRIEF DESCRIPTION OF THE DRAWINGS

The invention will become more fully understood from the detailed description given herein below illustration only, and thus is not limitative of the present invention, and wherein:

FIG. 1 is a schematic view showing the conventional heat dissipating system of the electronic apparatus;

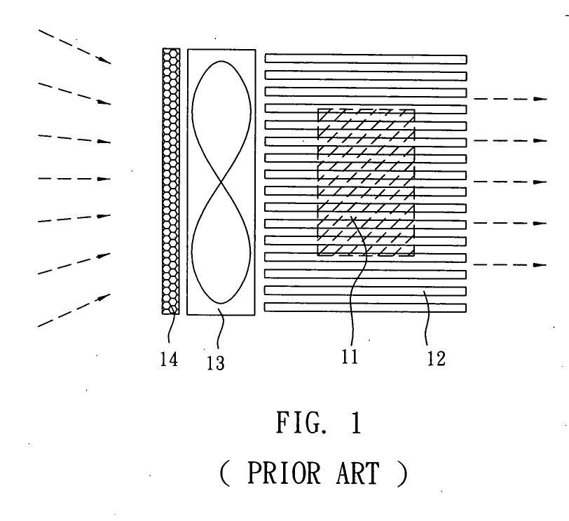

FIG. 2 is a schematic view showing a heat dissipating system according to a preferred embodiment of the invention;

FIG. 3 is a schematic view showing another heat dissipating system according to the embodiment of the invention; and

FIG. 4 is a flowchart showing a heat dissipating method according to a preferred embodiment of the invention.

### DETAILED DESCRIPTION OF THE INVENTION

The present invention will be apparent from the following detailed description, which proceeds with reference to the accompanying drawings, wherein the same references relate to the same elements.

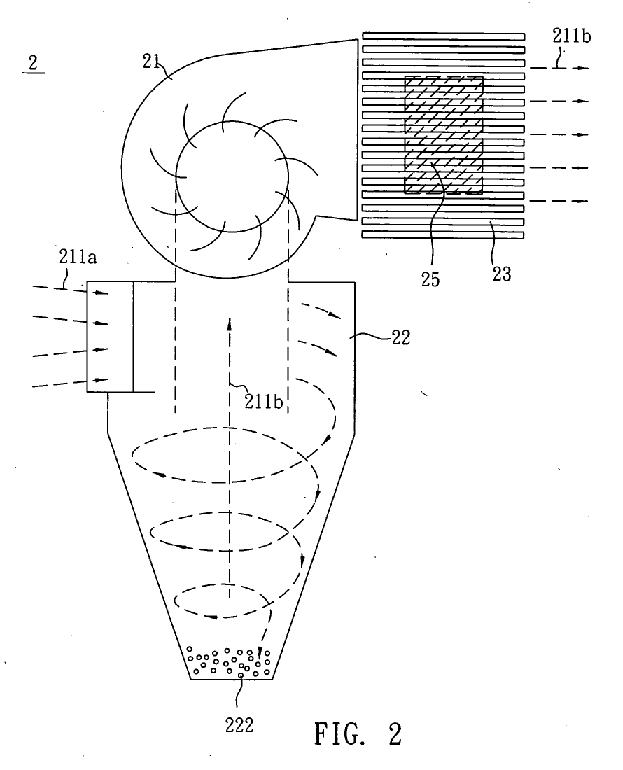

FIG. 2 is a schematic view showing a heat dissipating system according to a preferred embodiment of the invention. With reference to FIG. 2, a heat dissipating system 2, which is applied to a heat source 25, includes a fan 21, a dust-separating apparatus 22 and a heat sink 23.

In the embodiment, the fan 21 is an axial-flow fan or a centrifugal fan. When the fan 21 rotates, it can collect air from the exterior of the heat dissipating system 2 to generate an airflow 211a. Then, the airflow 211a flows into the dust-separating apparatus 22. Based on the centrifugal force and gravity force, the dusts 222 carried by the airflow 211a will be settled down to the bottom of the dust-separating apparatus 22. The separated airflow 211b is clean and enters the fan 21 directly. After that, the fan 21 blows the airflow 211b to the heat source 25 and the heat sink 23 to dissipate the heat away from the heat source 25.

The heat sink 23 is in contact with the heat source 25, so that the heat generated by the heat source 25 can be directly transferred to the heat sink 23. Then, the separated airflow 211b blows over the heat sink 23 to dissipate the heat away from the heat source 25. The fan 21 is located adjacent to the heat sink 23 for enhancing the heat dissipation effect of the heat source. As shown in FIG. 2, the fan 21 is located at one side of the heat sink 23, and the heat sink 23 is located above the heat source 25.

The dust-separating apparatus 22 is located adjacent to the heat source 25 and is, for example, a cone-shaped cyclonic separator. In this embodiment, the dust-separating apparatus 22 is coupled to the fan 21, so that the separated airflow 211b directly enters the fan 21 from the dust-separating apparatus 22 and is then blown out from the fan 21. Since the original airflow 211a is processed by the dust-separating apparatus 22 to separate the dust(s) 222, the separated airflow 211b entering the fan 21 is clean airflow without dusts. Thus, the dust can not be accumulated on the heat sink 23 or the heat source 25. Accordingly, the heat dissipation efficiency of the heat dissipating system 2 can be enhanced, and the interior of the heat dissipating system 2 can keep clean.

In the current embodiment, the heat source 25 is a electronic device, such as a CPU, memory, chipset, transistor, server, high-level graphic card, hard drive, power supply, vehicle control system, multimedia electronic apparatus, wireless access point, high-level game machine (PS3, XBOX, or Nintendo), or the likes.

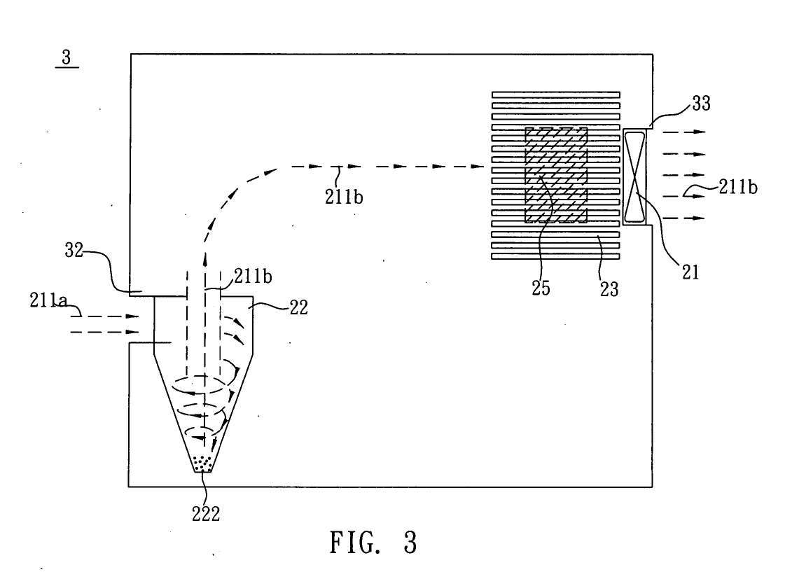

In addition, except being disposed at the entrance of the heat dissipating system 2, the fan 21 may be disposed at an exit of the heat dissipating system 2. FIG. 3 is a schematic view showing another heat dissipating system according to the embodiment of the invention. With reference to FIG. 3, the fan 21 is located at an exit 33 of the heat dissipating system 3. The dust-separating apparatus 22 is still located at the entrance 32 and is disposed far from the fan 21. In this case, no matter the fan 21 is located at the entrance 32 or the exit 33, the airflow 211a, which is generated by collecting air from the exterior of the heat dissipating system 3, can enter the heat dissipating system 3 from the entrance 32 and then flows into the dust-separating apparatus 22. The dust 222 carried by the airflow 211a is then separated and collected by the dust-separating apparatus 22. The separated clean airflow 211b flows over the heat sink 23. After that, the fan 21 rotates to force the airflow 211b, which carries the heat, to travel to the exterior of the heat dissipating system 3. Thus, the aim of carrying the heat away from the heat source 25 can be achieved.

Because the airflow 211a has been processed by the dust-separating apparatus 22 to separate the dust 222, the airflow 211b, which flows over the heat sink 23, is confirmed to be the clean airflow without dusts. Thus, the dust can not be accumulated on the heat sink 23 or the heat source 25. Accordingly, the heat dissipation efficiency of the heat dissipating system 2 can be enhanced, and the interior thereof can keep clean.

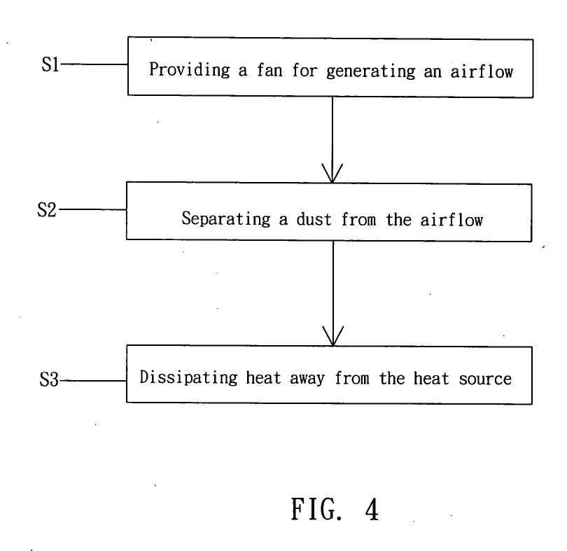

FIG. 4 is a flowchart showing a heat dissipating method according to a preferred embodiment of the invention. With reference to FIG. 4, the heat dissipating method includes the following steps.

In the step S1, a fan rotates to generate an airflow.

Then, in the step S2, a dust-separating apparatus is utilized to separate a dust from the airflow.

Finally, in the step S3, the heat is dissipated away from the heat source by the separated airflow.

Since the heat dissipating method of the embodiment can be applied to the heat dissipating system 2 or 3 shown in FIG. 2 or FIG. 3, and the implements and effects related to the heat dissipating method are discussed in the previous embodiment, the detailed descriptions are omitted for concise purpose.

In summary, the heat dissipating system and method of the invention is to separate the dust carried by the airflow in advance, and then to blow the separated airflow over the heat source. Thus, the dusts in the heat dissipating system can be reduced so as to prevent the dusts from being accumulated on the heat source or heat sink. Accordingly, the heat dissipating system of the invention can keep clean and is free from being affected by the accumulated dusts, so that the heat dissipation efficiency thereof can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat dissipating system, applied to a heat source generating heat, comprising:
a fan for generating an airflow by collecting air from an exterior of the heat dissipating system; and
a dust-separating apparatus, wherein after the airflow flows into the dust-separating apparatus, the dust-separating apparatus separates a dust from the airflow, and then the separated airflow dissipates the heat away from the heat source.

2. The heat dissipating system of claim 1, further comprising:
a heat sink contacting with the heat source, wherein the heat generated by the heat source is directly conducted to the heat sink, and the separated airflow blows over the heat sink to dissipate the heat away from the heat source.

3. The heat dissipating system of claim 2, wherein the fan is disposed adjacent to the heat sink.

4. The heat dissipating system of claim 1, wherein the dust-separating apparatus is coupled to the fan so that the separated airflow directly enters the fan from the dust-separating apparatus and is then blown out from the fan.

5. The heat dissipating system of claim 1, wherein the dust-separating apparatus is located far from the fan.

6. The heat dissipating system of claim 1, wherein the fan is disposed adjacent to the heat source.

7. The heat dissipating system of claim 1, wherein the fan is located at an entrance or an exit of the heat dissipating system.

8. The heat dissipating system of claim 1, wherein the dust-separating apparatus is a cyclonic separator.

9. The heat dissipating system of claim 8, wherein the cyclonic separator has a shape of cone.

10. The heat dissipating system of claim 1, wherein the fan is an axial-flow fan or a centrifugal fan.

11. A heat dissipating method, applied to a heat source generating heat, comprising steps of:
providing a fan for generating an airflow;
separating a dust from the airflow by a dust-separating apparatus; and
dissipating heat away from the heat source by the separated airflow.

12. The method of claim 11, further comprising:
directly conducting the heat generated by the heat source to a heat sink; and
blowing the separated airflow over the heat sink to dissipate the heat away from the heat source.

13. The method of claim 12, wherein the fan is disposed adjacent to the heat sink.

14. The method of claim 11, wherein the dust-separating apparatus is coupled to the fan, so that the separated airflow directly enters the fan from the dust-separating apparatus and is then blown out from the fan.

15. The method of claim 11, wherein the dust-separating apparatus is located far from the fan.

16. The method of claim 11, wherein the fan is located at an entrance or an exit of the heat dissipating system.

17. The method of claim 11, wherein the dust-separating apparatus is a cyclonic separator having a shape of cone.

18. The method of claim 11, wherein the fan is an axial-flow fan or a centrifugal fan.
